(19) United States
(12) Patent Application Publication
(10) Pub. No.: US 2010/0024733 A1
(43) Pub. Date: Feb. 4, 2010

(54) FILM FORMATION APPARATUS AND FILM FORMATION METHOD USING THE SAME

(75) Inventors: Takehiko Soda, Yokohama-shi (JP); Masataka Eida, Mobara-shi (JP); Kazushi Miyata, Mobara-shi (JP)

Correspondence Address: FITZPATRICK CELLA HARPER & SCINTO, 1290 Avenue of the Americas, NEW YORK, NY, 10104-3800, US

(73) Assignees: CANON KABUSHIKI KAISHA, Tokyo (JP); HITACHI DISPLAYS, LTD., Mobara-shi (JP)

(21) Appl. No.: 12/509,785

(22) Filed: Jul. 27, 2009

(30) Foreign Application Priority Data
Jul. 31, 2008 (JP) 2008-197611

(51) Int. Cl. C23C 16/04; B32B 37/00

(52) U.S. Cl. 118/730; 118/728; 156/60

(57) ABSTRACT

Provided are a film formation apparatus and a film formation method which are capable of forming a pixel pattern with good dimensional accuracy and with reduced misalignment in a plane direction between a substrate and a mask when the substrate is pressed against the mask. The film formation apparatus includes an alignment mechanism for aligning a substrate and a mask with each other and a pressing mechanism for pressing the substrate against the mask with a contact member provided to one end of a pressing body, which are provided in a vacuum chamber. After alignment between the substrate and the mask by the alignment mechanism, the contact member of the pressing body is brought into contact with a surface of the substrate, which is on a side opposite to the mask, to press the substrate.

### BACKGROUND OF THE INVENTION

1. Field of the Invention

The present invention relates to a film formation apparatus and a film formation method using the same.

2. Description of the Related Art

Conventionally, in a method of manufacturing an organic electroluminescence (EL) device, a mask film formation method of arranging a mask for film formation to be in close contact with a glass substrate is frequently used. As an example of such a mask film formation method, there is a mask vapor deposition method. According to the vapor deposition method, a pattern of an organic EL layer may be formed with good accuracy. In recent years, along with an increase in resolution of an organic EL panel, patterning becomes finer and finer. Therefore, even slight misalignment in a plane direction between a pixel pattern formed on the glass substrate and a mask or insufficient adhesion between the glass substrate and the mask for vapor deposition disadvantageously degrades quality.

In particular, it is known that the insufficient adhesion between the glass substrate and the mask is also caused by slight distortion of the mask or the sag of the mask itself under its own weight. Therefore, a magnetic mask or a metal mask is used as the mask for vapor deposition to attract the mask from the back side of the glass substrate by a magnet. In this manner, the substrate and the mask may be brought into close contact with each other. However, when a strong magnet is used, the mask and the substrate stick to each other. As a result, in some cases, the mask and the glass substrate may not be easily separated away from each other. On the other hand, when a magnetic force is small, there is fear that a gap may be generated between the mask and the substrate to cause a vapor-deposited film to flow into the gap. As a measure against this, the following vapor deposition method is proposed in Japanese Patent Application Laid-Open No. 2005-158571. According to the vapor deposition method, after alignment between the substrate and the mask, the substrate is dynamically pressed against the mask to bring the substrate and the mask in close contact with each other.

In the method described in Japanese Patent Application Laid-Open No. 2005-158571, however, it is difficult to control to press the substrate in a direction vertical to the substrate in a strict manner when the substrate is dynamically pressed against the mask. Even with a slight shift of a pressing direction from the vertical direction, there is a fear that a force in the plane direction may be applied to the substrate to cause the misalignment in the plane direction between the substrate and the mask. As a result, the misalignment in the plane direction between the pixel pattern formed on the substrate and the pattern of the mask adversely occurs.

### SUMMARY OF THE INVENTION

In view of the problem described above, the present invention has an object of providing a film formation apparatus capable of forming a pixel pattern with good dimensional accuracy and with reduced misalignment in a plane direction between a substrate and a mask when the substrate is pressed against the mask, and a film formation method using the film formation apparatus.

A film formation apparatus according to the present invention includes: an alignment mechanism for aligning a substrate and a mask with each other; a pressing mechanism for pressing the substrate aligned with the mask against the mask; and a vapor depositing source, the alignment mechanism, the pressing mechanism, and the vapor depositing source being provided in a film forming chamber, wherein the pressing mechanism includes a pressing body including a contact member to be brought into contact with a surface of the substrate on a side opposite to the mask, and wherein a friction coefficient between the contact member and the substrate is smaller than a friction coefficient between the substrate and the mask.

According to the film formation apparatus and the film formation method using the film formation apparatus according to the present invention, in the step of pressing the substrate against the mask to improve adhesiveness between the mask and the substrate, misalignment in a plane direction between the substrate and the mask may be suppressed. As a result, a pixel pattern arranged on the substrate may be formed with reduced misalignment in a plane direction and with good dimensional accuracy.

Further features of the present invention become apparent from the following description of exemplary embodiments with reference to the attached drawings.

### BRIEF DESCRIPTION OF THE DRAWINGS

FIGS. 1A and 1B illustrate a vapor deposition apparatus according to an embodiment of the present invention, in which FIG. 1A is a schematic view illustrating a step of aligning a substrate and a mask with each other and FIG. 1B is a schematic view of a pressing step of bringing the substrate and the mask into close contact with each other.

FIG. 2 is a schematic front view illustrating an example of a pressing body according to the embodiment of the present invention.

FIG. 3 is a schematic front view illustrating another example of the pressing body according to the embodiment of the present invention.

FIG. 4 is a schematic front view illustrating a still another example of the pressing body according to the embodiment of the present invention.

### DESCRIPTION OF THE EMBODIMENT

An embodiment for carrying out the present invention is described referring to the accompanying drawings.

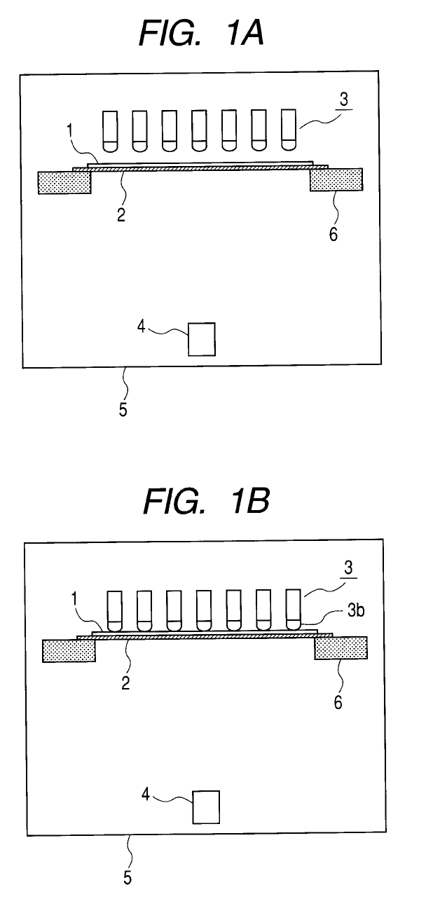

FIGS. 1A and 1B illustrate a film formation apparatus according to an embodiment of the present invention. FIG. 1A is a schematic view illustrating a step of aligning a substrate and a mask with each other, whereas FIG. 1B is a schematic view illustrating a pressing step of bringing the substrate and the mask into close contact with each other.

As illustrated in FIG. 1A, a vapor deposition apparatus which is the film formation apparatus includes an alignment mechanism (not shown) for aligning a substrate 1 and a mask 2 with each other, a pressing mechanism for pressing the substrate 1 against the mask 2, and a vapor depositing source 4. The alignment mechanism, the pressing mechanism, and the vapor depositing source 4 are provided in a vacuum chamber 5 which is a film forming chamber. Alignment marks for alignment are provided to each of the substrate 1 and the mask 2. Alignment between the substrate 1 and the mask 2 is performed by adjusting a positional relation between the alignment marks respectively formed on the substrate 1 and the mask 2 in a state where the substrate 1 and pressing bodies 3 of the pressing mechanism are separated from each other.

The pressing bodies 3 are arranged to be brought closer to the substrate 1 from the side opposite to the mask 2 which is supported by a mask supporting table 6 after the alignment between the substrate 1 and the mask 2. Then, as illustrated in FIG. 1B, the pressing bodies 3 press the substrate 1 against the mask 2. Reference numeral 3b denotes a contact member.

In this embodiment, the vapor depositing source 4 is provided below the substrate 1. The positions of the substrate 1 and the vapor depositing source 4 may be fixed or may be provided in a relatively movable manner. Moreover, a surface of the substrate 1, on which the film is to be formed, is arranged to be oriented downward, whereas the mask 2 is provided on the bottom side of the substrate 1. However, the orientation of the surface, on which the film is to be formed, and the positional relation between the substrate 1 and the mask 2 are not limited thereto as long as a film forming material may be patterned on the surface of the substrate 1, on which the film is to be formed. For example, the substrate 1 and the mask 2 may be vertically arranged. Moreover, a chamber for bringing the substrate 1 and the mask 2 into close contact with each other and a chamber for vapor deposition may be provided independently of each other to be continuously connected in a vacuum. It is desirable that the degree of vacuum be kept to 1×10⁻³ Pa or less.

Next, the pressing body is described.

In the present invention, the contact body 3b is provided to one end of a main body of each of the pressing bodies 3. The contact body 3b satisfies the relation of μ1>μ2, where μ1 represents a friction coefficient between the substrate 1 and the mask 2 and μ2 represents a friction coefficient between the substrate 1 and the contact member 3b. Even when a pressing direction is shifted from a direction vertical to the substrate 1, a frictional force acting between the substrate 1 and the contact member 3b is smaller than a frictional force acting between the substrate 1 and the mask 2. Accordingly, the frictional force generated between the substrate 1 and the mask 2 is larger than a force applied by the pressing bodies 3 (contact members 3b) to the substrate 1 in a plane direction. Therefore, the misalignment in the plane direction between the substrate and the mask may be suppressed.

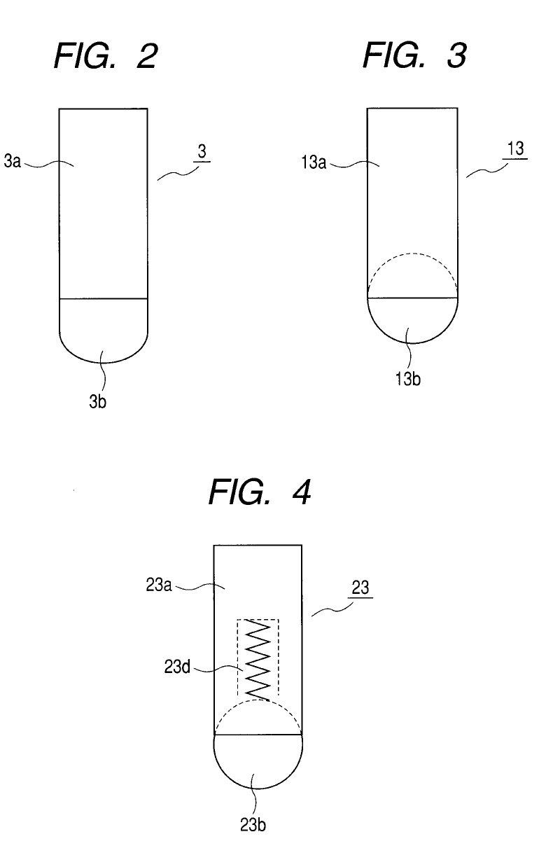

FIG. 2 is a schematic front view illustrating an example of the pressing body 3. As illustrated in FIG. 2, the contact member 3b is provided to one end of a main body 3a of the pressing body 3. The position at which the contact member 3b is provided is not limited to one end of the main body 3a of the pressing body 3 as long as the frictional force generated between the pressing body 3 and the substrate 1 may be reduced.

In order to reduce the friction coefficient between the substrate 1 and the contact member 3b, a fluorine resin having a small friction coefficient is suitably used as a material of the contact member 3b. For example, polytetrafluoroethylene (PTFE), tetrafluoroethylene perfluoroalkylvinylether copolymer (PFA), and tetrafluoroethylene hexafluoropropylene copolymer (FEP) may be suitably used.

The entire contact member 3b of the pressing body 3 may be formed of the above-mentioned material having a small friction coefficient. Alternatively, only a surface of one end of the pressing body 3 may be covered with the above-mentioned material having a small friction coefficient.

FIG. 3 is a schematic front view illustrating a variation of the pressing body.

A rotating body 13b as illustrated in FIG. 3 is provided to one end of a main body 13a of a pressing body 13 as a contact member. When the substrate 1 is pressed, the rotating body 13b brought into contact with the substrate 1 rotates on the substrate 1. As a result, the force applied to the substrate 1 in the plane direction may be reduced. With this structure, the pressing force of the pressing body 13 may be transmitted through the rotating body 13b as the force for pressing the substrate 1. However, the pressing of the substrate 1 is not limited thereto as long as the adhesiveness between the substrate 1 and the mask 2 may be improved. For example, the pressing mechanism may press the substrate 1 only by a weight of the rotating bodies 13b. As a shape of the rotating body 13b, a roller-like shape or a spherical shape is preferred. However, the shape of the rotating body 13b is not limited thereto as long as the shape allows the rotating body 13b to easily rotate in the plane direction with respect to the substrate 1 when the rotating body 13b is brought into contact with the substrate 1. Moreover, a metal, a resin, and glass may be used as a material of the rotating body 13b, but the material of the rotating body 13b is not limited thereto. Any material may be used as long as the material has a function of rotating the rotating body 13b on the substrate 1. Alternatively, a surface of the rotating body 13b may be covered with the fluorine resin or the like.

The number of the pressing bodies may be one, but it is preferable to arrange a plurality of the pressing bodies as illustrated in FIG. 1. With such arrangement, even when it is difficult to ensure a sufficient adhesiveness over the entire region of each of the substrate and the mask, the adhesiveness between the substrate and the mask may be improved by pressing a plurality of regions of the substrate by the plurality of pressing bodies. The positions of the pressing bodies may be appropriately selected to prevent the occurrence of the misalignment between the substrate and the mask. Moreover, it is more desirable to appropriately select the degree of pressing force according to the strength of the mask or the adhesiveness between the substrate and the mask.

FIG. 4 is a schematic front view illustrating another variation of the pressing body.

An elastic body 23d may be provided between a pressing body 23 and a rotating body 23b to allow a force of the pressing body 23 to be transmitted through the elastic body 23d to the rotating body 23b to press the substrate 1. For example, there may be provided a pressing mechanism for pressing the substrate 1 with the pressing body 23 including the rotating body 23b which is connected to the elastic body 23d fixed to the main body 23a. Even when the attachment accuracy of the pressing body 23 or the flatness of the substrate 1 or the mask 2 is not sufficient, the adhesiveness between the substrate 1 and the mask 2 may be improved by an elastic force of the elastic body 23d. In addition, the substrate 1 and the mask 2 may be prevented from being damaged. Moreover, the adhesiveness between the substrate 1 and the mask 2 may be further increased and the substrate 1 and the mask 2 may be prevented from being damaged by adjusting a spring strength of the elastic body 23d according to the strength of the substrate 1 or the mask 2.

The mask 2 has a thin plate-like shape, which partially or entirely has an opening. In a vapor deposition step which requires a finer pattern, it is suitable to set a thickness of a mask portion to 100 μm or less, and preferably, 50 μm or less. As a material of the mask 2, copper, nickel, stainless steel and the like may be used. The mask portion may be fabricated by electroforming using nickel, or a nickel alloy such as a nickel-cobalt alloy, an invar material made of a nickel-iron alloy, or a super invar material made of a nickel-iron-cobalt alloy. In particular, the invar material and the super-invar material each have a thermal expansion coefficient of 0.5×10⁻⁶ to 2×10⁻⁶/° C., which is smaller than those of the other metals, and thus the deformation of the mask due to the thermal expansion at the time of vapor deposition may be prevented. Moreover, it is difficult to realize sufficient dimensional accuracy of the opening over a large region for the mask for a large-size substrate. Therefore, it is also suitable to fabricate a frame portion having high strength by using the invar material and to form a thin mask on an region surrounded by the frame portion.

As the substrate, a silicon substrate, a glass substrate, or a plastic substrate may be used according to the intended use. For a large-size display, a substrate obtained by forming a drive circuit or a pixel electrode in advance on non-alkali glass is preferably used.

The vapor deposition apparatus and the vapor deposition method using the vapor deposition apparatus have been described in this embodiment, but the present invention is similarly applicable to the film formation apparatus for forming a protective film by a CVD method or a sputtering method.

### EXAMPLE 1

An organic EL device was fabricated on the glass substrate by the film formation apparatus. A known light-emitting material was placed in a film forming source which is the vapor depositing source. In the film forming chamber, the substrate was located with the surface, on which the film was to be formed, being oriented downward.

The glass substrate made of non-alkali glass with a thickness of 0.5 mm and dimensions of 400 mm×500 mm was used as the substrate. On the substrate, thin-film transistors (TFTs) and electrode wirings were formed in a matrix pattern by a conventional method. The size of one pixel was 30 μm×120 μm. A display region of the organic EL device was arranged in the center of the substrate to have dimensions of 350 mm×450 mm. For the mask, a tension was applied to the mask portion having a thickness of 50 μm and dimensions of 400 mm×500 mm to weld the mask portion to the frame having a thickness of 100 mm. The mask obtained by thus integrating the mask portion to the frame was used. The invar material was used as a material of the mask portion and the frame.

The pressing body was capable of pressing the rotating body similar to that illustrated in FIG. 4 with the elastic body. For the pressing body, a bar having a diameter of 10 mm was obtained by cutting SUS303. At a tip of the bar, which was to be brought into contact with the substrate, the rotating body obtained by shaping the fluorine resin was attached as the contact member. The contact member provided to one end of the main body of the pressing body had a spherical shape. Twenty-five pressing bodies were arranged to evenly press twenty-five positions on the surface of the substrate. A height position of each of the pressing bodies was adjusted to allow the twenty-five pressing bodies to press the substrate almost simultaneously. A friction coefficient between the surface of the contact member provided to one end of the main body of the pressing body and the surface of the substrate, which was measured by a known method, was 0.1. On the other hand, a friction coefficient between the surface of the substrate and the surface of the mask was 0.5.

A step of fabricating the organic EL device is described. First, anode electrodes were formed on the glass substrate including the TFTs to arrange a light-emitting region having dimensions of 25 μm×100 μm in the center of the pixel. Next, by using the film formation apparatus and a known mask for vapor deposition, the alignment mechanism was operated in a vacuum state to bring the substrate and the mask closer to each other to have a distance of 0.1 mm therebetween. Next, the substrate was operated by the alignment mechanism to align the substrate and the mask with each other while the alignment marks provided on the substrate and the alignment marks provided on the mask were being monitored by using a CCD camera. After the alignment mechanism was operated to bring the substrate into contact with the mask, the spherical tips of the pressing bodies were lowered to press the substrate against the mask with the pressing bodies.

Next, a film was formed of a known light-emitting material to have a thickness of 700 Å by using a vacuum vapor deposition method at a vapor-depositing rate of 3 Å per second under a condition that the degree of vacuum was 2×10⁻⁴ Pa. A shape of the film formed on the substrate was checked after the film formation. Then, the film size was almost the same as that of the opening of the mask, and no flow of the film into a gap between the substrate and the mask was observed. Moreover, the thin film was appropriately arranged on the anode electrode. As a result, the organic EL device having the organic EL layer pattern formed with good dimensional accuracy was fabricated by the film formation apparatus and the film formation method according to the present invention.

### EXAMPLE 2

For the pressing body, a bar having a diameter of 10 mm was obtained by cutting SUS303. At a tip of the bar, which was to be brought into contact with the substrate, the rotating body made of SUS303 was attached as the contact member. The twenty-five pressing bodies were arranged to evenly press the twenty-five positions on the surface of the substrate. The height position of each of the pressing bodies was adjusted to allow the twenty-five pressing bodies to press the substrate almost simultaneously. The other conditions for the used mask and substrate were the same as those of Example 1.

As in the case of Example 1, anode electrodes were formed on the glass substrate including the TFTs, and by using the film formation apparatus and a known mask for vapor deposition, alignment between the substrate and the mask was performed in a vacuum state. After the alignment mechanism was operated to bring the substrate into contact with the mask, the pressing mechanism was lowered to press the substrate against the mask with the rotating bodies each provided to one end of the pressing bodies.

Next, a film was formed of a known light-emitting material to have a thickness of 700 Å by using a vacuum vapor deposition method at a vapor-depositing rate of 3 Å per second under a condition that the degree of vacuum was 2×10⁻⁴ Pa. A shape of the film formed on the substrate was checked after the film formation. Then, the film size was almost the same as that of the opening of the mask, and no flow of the film into a gap between the substrate and the mask was observed. Moreover, the thin film was appropriately arranged on the anode electrode. As a result, the organic EL device having the organic EL layer pattern formed with good dimensional accuracy was successfully fabricated by the film formation apparatus and the film formation method according to the present invention.

### EXAMPLE 3

For the pressing body, the bar having a diameter of 10 mm was obtained by cutting SUS303. At the tip of the bar, which was to be brought into contact with the substrate, the rotating body made of SUS303 was attached as the contact member. A spring which is the elastic body made of the fluorine resin was provided inside the main body of the pressing body to allow the force of the pressing body to be transmitted to the rotating body through the spring. The twenty-five pressing bodies were arranged to evenly press the twenty-five positions on the surface of the substrate. The height position of each of the pressing bodies was adjusted to allow the twenty-five pressing bodies to press the substrate almost simultaneously. The other conditions for the used mask and substrate were the same as those of Example 1.

As in the case of Example 1, the anode electrodes were formed on the glass substrate including the TFTs, and by using the film formation apparatus and a known mask for vapor deposition, alignment between the substrate and the mask was performed in a vacuum state. After the alignment mechanism was operated to bring the substrate into contact with the mask, the pressing mechanism was lowered to press the substrate against the mask with the rotating bodies each provided to one end of the pressing bodies.

Next, a film was formed of a known light-emitting material to have a thickness of 700 Å by using a vacuum vapor deposition method at a vapor-depositing rate of 3 Å per second under a condition that the degree of vacuum was 2×10⁻⁴ Pa. A shape of the film formed on the substrate was checked after the film formation. Then, the film size was almost the same as that of the opening of the mask, and no flow of the film into a gap between the substrate and the mask was observed. Moreover, the thin film was appropriately arranged on the anode electrode. As a result, the organic EL device having the organic EL layer pattern formed with good dimensional accuracy was successfully fabricated by the film formation apparatus and the film formation method according to the present invention.

### COMPARATIVE EXAMPLE

For the pressing body, the bar having a diameter of 10 mm was obtained by cutting SUS303. The tip of the bar, which was to be brought into contact with the substrate, was formed in a spherical shape. The twenty-five pressing bodies were arranged to evenly press the twenty-five positions on the surface of the substrate. The height position of each of the pressing bodies was adjusted to allow the twenty-five pressing bodies to press the substrate almost simultaneously. The other conditions for the used mask and substrate were the same as those of Example 1.

As in the case of Example 1, the anode electrodes were formed on the glass substrate including the TFTs, and by using the film formation apparatus and a known mask for vapor deposition, alignment between the substrate and the mask was performed in a vacuum state. After the alignment mechanism was operated to bring the substrate into contact with the mask, the pressing mechanism was lowered to press the substrate against the mask with the pressing bodies.

Next, the film was formed of the known light-emitting material to have the thickness of 700 Å by the vacuum vapor deposition method at the vapor-depositing rate of 3 Å per second under the condition that the degree of vacuum was 2×10⁻⁴ Pa. The shape of the film formed on the substrate was checked after the film formation. Then, the film size was almost the same as that of the opening of the mask, and no flow of the film into the gap between the substrate and the mask was observed. However, the thin film was arranged out of alignment with the position of the anode electrode. Therefore, the thin film was not appropriately located.

While the present invention has been described with reference to embodiments, it is to be understood that the invention is not limited to the disclosed embodiments. The scope of the following claims is to be accorded the broadest interpretation so as to encompass all such modifications and equivalent structures and functions.

This application claims the benefit of Japanese Patent Application No. 2008-197611, filed Jul. 31, 2008, which is hereby incorporated by reference herein in its entirety.

What is claimed is:

1. A film formation apparatus, comprising:
an alignment mechanism for aligning a substrate and a mask with each other;
a pressing mechanism for pressing the substrate aligned with the mask against the mask; and
a vapor depositing source,
the alignment mechanism, the pressing mechanism, and the vapor depositing source being provided in a film forming chamber,
wherein the pressing mechanism includes a pressing body including a contact member to be brought into contact with a surface of the substrate on a side opposite to the mask, and
wherein a friction coefficient between the contact member and the substrate is smaller than a friction coefficient between the substrate and the mask.

2. The film formation apparatus according to claim 1, wherein the contact member comprises a rotating body provided to one end of the pressing body.

3. The film formation apparatus according to claim 2, wherein the rotating body provided to the one end of the pressing body has a spherical shape.

4. The film formation apparatus according to claim 2, further comprising an elastic body provided between the pressing body and the rotating body,
wherein a force of the pressing body is transmitted through the elastic body to the rotating body to press the substrate against the mask.

5. The film formation apparatus according to claim 1, wherein the pressing mechanism includes a plurality of the pressing bodies.

6. A film formation method of superimposing a mask on a substrate to perform vapor deposition, comprising:
aligning the substrate and the mask with each other; and
pressing the substrate aligned with the mask against the mask,
wherein the pressing includes bringing a contact member into contact with the substrate and pressing the substrate against the mask in a state where a friction coefficient between the contact member and the substrate is smaller than a friction coefficient between the substrate and the mask.
